(19) United States
(12) Patent Application Publication
(10) Pub. No.: US 2013/0320374 A1
(43) Pub. Date: Dec. 5, 2013

(54) Double-Layer Circuit Structure with High Heat-Dissipation Efficiency

(71) Applicant: KOCAM INTERNATIONAL CO. LTD., New Taipei City (TW)

(72) Inventor: Tsan-Jung Chen, New Taipei City (TW)

(73) Assignee: Kocam International Co., Ltd., New Taipei City (TW)

(21) Appl. No.: 13/890,248

(22) Filed: May 9, 2013

(30) Foreign Application Priority Data
Jun. 1, 2012 (TW) 101210548

(51) Int. Cl. H01L 33/64

(52) U.S. Cl. CPC H01L 33/647
USPC 257/98; 257/99

(57) ABSTRACT

The present invention relates to a double-layer circuit structure with high heat-dissipation efficiency, comprising: a first thermal-conductive and electric-insulating layer, a plurality of first metal pads, a second thermal-conductive and electric-insulating layer, a circuit layer, and an anti-soldering layer. In the double-layer circuit structure, the second thermal-conductive and electric-insulating layer disposed on the first thermal-conductive and electric-insulating layer has a plurality of openings, and a plurality of second metal pads of the circuit layer on the second thermal-conductive and electric-insulating layer are connected with the openings, respectively. Thus, after each of devices to be welded are soldered on two second metal pads, the solder would flow into the openings through the soldering points between the devices to be welded and the second metal pads, so as to sequentially flow onto the first metal pads. Therefore, the flow path of the solder becomes a heat-dissipating shortcut for heat dissipation.

### BACKGROUND OF THE INVENTION

1. Field of the Invention

The present invention relates to a circuit structure, and more particularly to a double-layer circuit structure with high heat-dissipation efficiency.

2. Description of the Prior Art

Recently, light emitting diode (LED) devices are widely used in lighting device of human life. However, because the LED devices would produce high temperature when emitting, the heat dissipation of the LED devices must be considered when applying the LED devices.

Please refer to FIG. 1, which illustrates a cross-sectional view of a conventional LED driving circuit. As shown in FIG. 1, the conventional LED driving circuit 1′ includes: an aluminum substrate 10′, a thermal-conductive and electric-insulating layer 11′, a circuit layer 12′, wherein a plurality of LED devices 13′ are disposed and welded on the circuit layer 12′. When the LED devices 13′ emit light, the heat produced by the LED devices 13′ would be conducted to the thermal-conductive and electric-insulating layer 11′, and then further conducted to the aluminum substrate 10′. Therefore, the heat produced by the LED devices 13′ can be dissipated by such heat conductive path.

Through above description, it is able to know that the conventional LED driving circuit 1′ cannot effectively rule the heat produced by the LED devices 13′, the reason is that there are a large thermal conductivity difference existing between the the thermal-conductive and electric-insulating layer 11′ and aluminum substrate 10′. Accordingly, the manufactures propose a circuit structure with double layers for solving the drawbacks of the conventional LED driving circuit 1′. Please refer to FIG. 2, which illustrates a cross-sectional view of the circuit structure with double layers. As shown in FIG. 2, the circuit structure with double layers 1″ includes: a first thermal-conductive and electric-insulating layer 10″, a first circuit layer 14″, a second thermal-conductive and electric-insulating layer 11″, and a second circuit layer 12″, wherein a plurality of LED devices 13″ are welded on the second circuit layer 12″.

The second thermal-conductive and electric-insulating layer 11″ is formed with a plurality of through holes 111″, used for connecting the first circuit layer 14″ and the second circuit layer 12″, in which there are thermal conductive objects being filled in the through holes 111′. So that, when the LED devices 13″ emit light, the heat produced by the LED devices 13″ would be conducted from the second circuit layer 12″ to the first circuit layer 14″ via the through holes 111″, and eventually conducted to the first thermal-conductive and electric-insulating layer 10″.

In the circuit structure with double layers 1″, the through holes 111′ are called heat-dissipating shortcuts for heat dissipation of the LED devices 13″; however, the through holes 111′ results some problem in the circuit structure with double layers 1″:

1.In order to make the through holes 111′ exactly become the heat-dissipating short cuts of the top circuit layer 12″ and the lower circuit layer 14″, it must especially notice the relative position of the top circuit layer 12″ and the lower circuit layer 14″ when fabricating the through holes 111′. For this reason, it is able to know that the fabrication of the through holes 111′ causes the manufacturing process of the circuit structure with double layers 1″ become complex.

2. Inheriting to above point 1, moreover, it needs to further determine whether the thermal conductive objects are full filled the through holes 111′, wherein the heat-dissipating shortcuts cannot formed between the top circuit layer 12″ and the lower circuit layer 14″ if the thermal conductive objects does not full filled the through holes 111′.

Accordingly, in view of the conventional LED driving circuit 1′ and the circuit structure with double layers 1″ still have shortcomings and drawbacks, the inventor of the present application has made great efforts to make inventive research thereon and eventually provided a double-layer circuit structure with high heat-dissipation efficiency.

### SUMMARY OF THE INVENTION

The primary objective of the present invention is to provide a double-layer circuit structure with high heat-dissipation efficiency, in which, the double-layer circuit structure consists of a top circuit layer, a top thermal-conductive and electric-insulating layer, a lower metal layer, and a lower thermal-conductive and electric-insulating layer. Particularly, the top thermal-conductive and electric-insulating layer includes a plurality of openings, and each of metal pads of the top circuit layer are respectively connected with the openings; thus, after each of devices to be welded are soldered on two metal pads, the solder would flow into the openings through the soldering points between the devices to be welded and the metal pads, so as to sequentially flow onto the lower metal layer. Therefore, the flow path of the solder becomes a heat-dissipating shortcut for heat dissipation.

Accordingly, to achieve the primary objective of the present invention, the inventor of the present invention provides a double-layer circuit structure with high heat-dissipation efficiency, comprising:

a first thermal-conductive and electric-insulating layer;

a plurality of first metal pads, disposed on the first thermal-conductive and electric-insulating layer;

a second thermal-conductive and electric-insulating layer, disposed on the first thermal-conductive and electric-insulating layer, and having a plurality of openings, wherein each of the openings are located over the inner edges of each of the first metal pads, respectively;

a circuit layer, formed on the second thermal-conductive and electric-insulating layer, and having a main circuit and a plurality of second metal pads connected to the main circuit, wherein each of the second metal pads are connected with the outer edges of each of the openings, respectively; moreover, each of the second metal pads and the openings are respectively located over each of the first metal pads when the second thermal-conductive and electric-insulating layer covered the first thermal-conductive and electric-insulating layer; and

an anti-soldering layer, covering the circuit layer, and having a plurality of soldering windows for exposing the second metal pads out;

wherein a plurality of devices to be welded are respectively soldered on the second metal pads via the soldering windows after being disposed on the anti-soldering layer, such that the devices to be welded are electrically connected to the circuit layer; moreover, each of the devices to be welded being soldered on two second metal pads, and the solder would flow into the openings through the soldering points between the devices to be welded and the second metal pads, so as to sequentially flow onto the first metal pads; therefore, the flow path of the solder becomes a heat-dissipating shortcut for heat dissipation.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein::

FIG. 1 is a cross-sectional view of a conventional LED driving circuit;

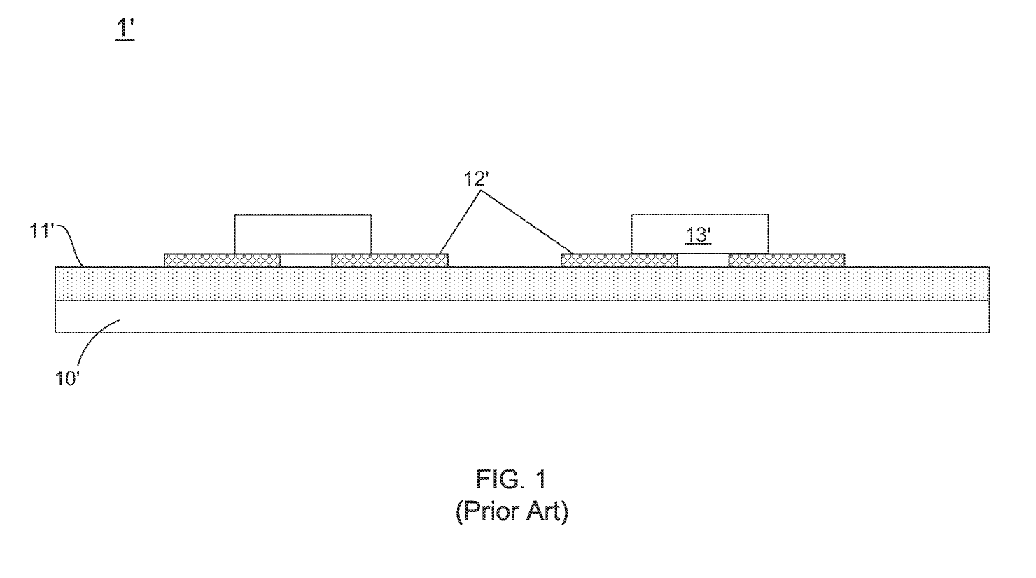

FIG. 2 is a cross-sectional view of a circuit structure with double layers;

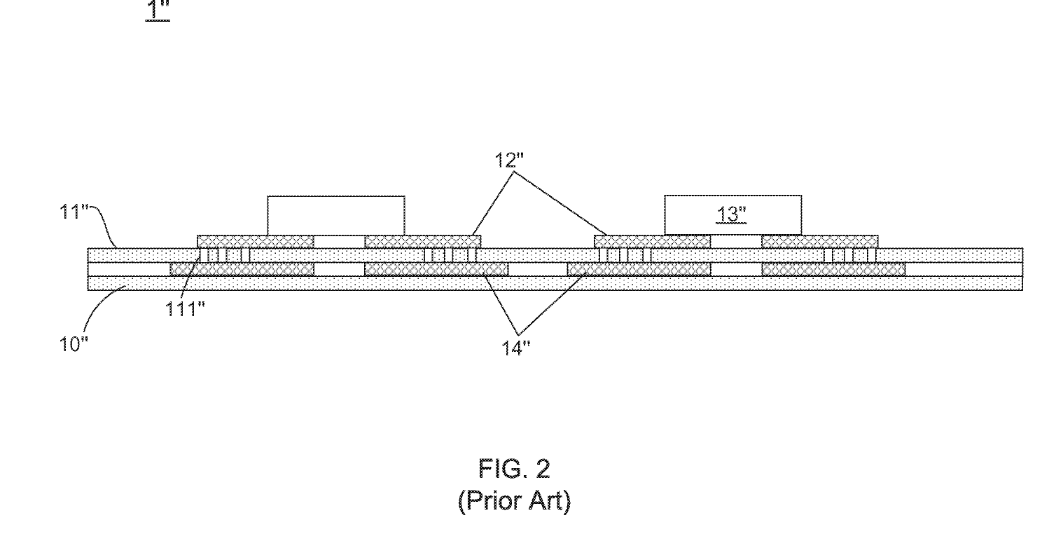

FIG. 3 is an exploded view of the double-layer circuit structure with high heat-dissipation efficiency according to the present invention;

FIG. 4 is a cross-sectional view of the double-layer circuit structure with high heat-dissipation efficiency according to the present invention;

FIG. 5 is a stereo view of a first thermal-conductive and electric-insulating layer of the double-layer circuit structure with high heat-dissipation efficiency;

FIG. 6 is a stereo view of an LED backlight module provided with the double-layer circuit structure;

FIG. 7 is a stereo view of an LED lamp tube provided with the double-layer circuit structure; and

FIG. 8 is a stereo view of an LED lamp provided with the double-layer circuit structure.

### DETAILED DESCRIPTION OF THE PREFERRED EMBODIMENTS

To more clearly describe a double-layer circuit structure with high heat-dissipation efficiency according to the present invention, embodiments of the present invention will be described in detail with reference to the attached drawings hereinafter.

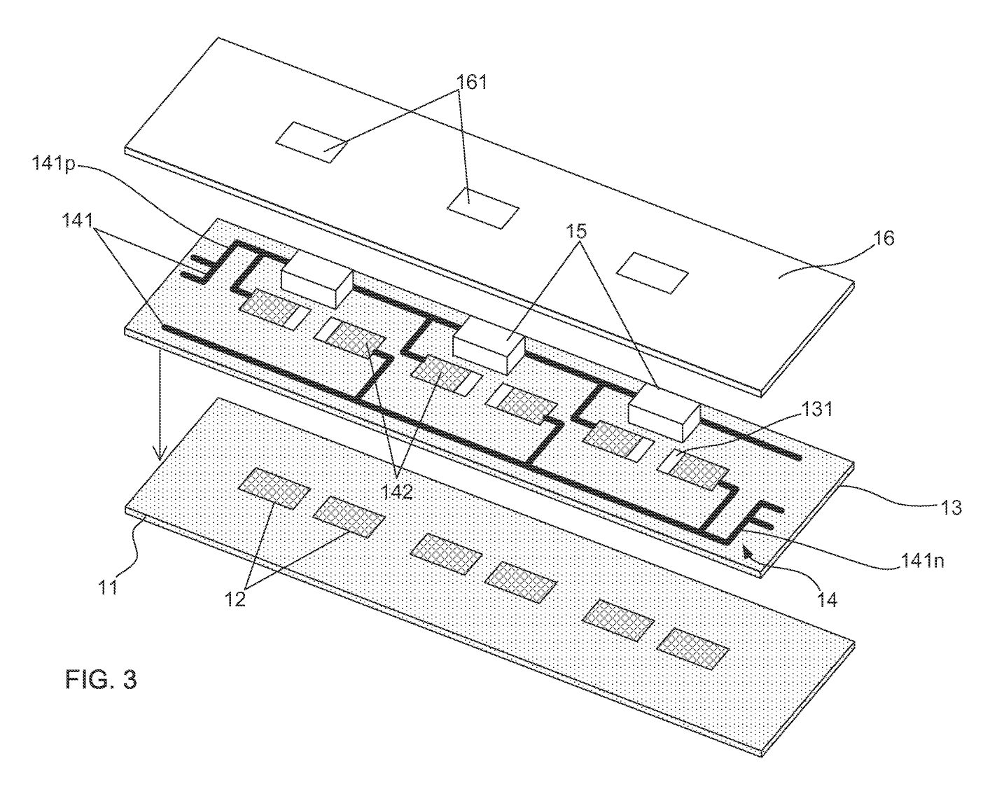

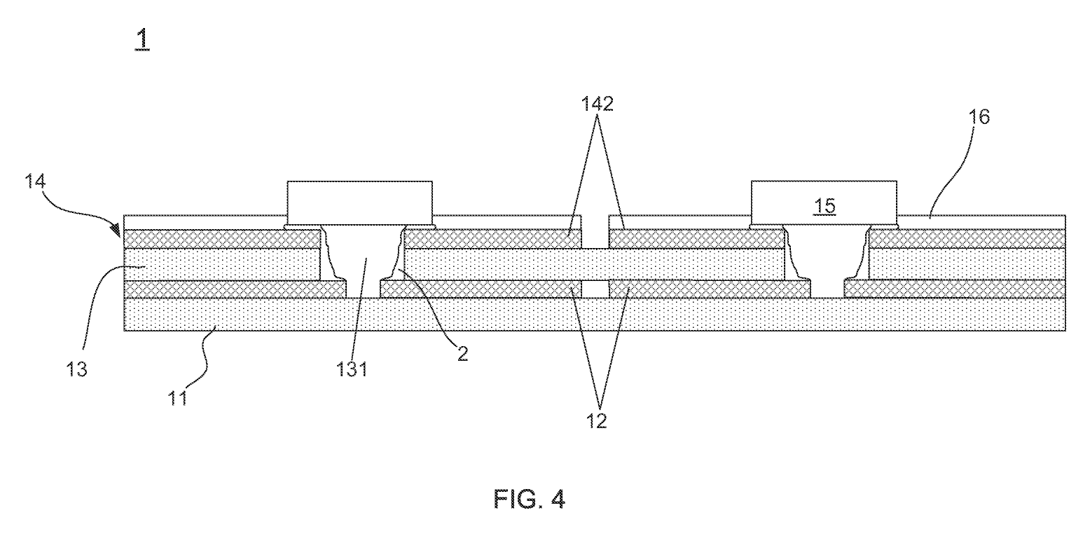

Please refer to FIG. 3 and FIG. 4, which respectively illustrate an exploded view and a cross-sectional view of the double-layer circuit structure with high heat-dissipation efficiency according to the present invention. As shown in FIG. 3 and FIG. 4, the double-layer circuit structure 1 of the present invention consists of: a first thermal-conductive and electric-insulating layer 11, a plurality of first metal pads 12, a second thermal-conductive and electric-insulating layer 13, a circuit layer 14, and an anti-soldering layer 16, wherein the first metal pads are disposed on the first thermal-conductive and electric-insulating layer 11.

The second thermal-conductive and electric-insulating layer 13 is disposed on the first thermal-conductive and electric-insulating layer 11, and has a plurality of openings 131, wherein each of the openings 131 are located over the inner edges of each of the first metal pads 12, respectively. In addition, the circuit layer 14 is formed on the second thermal-conductive and electric-insulating layer 13, and includes a main circuit 141 and a plurality of second metal pads 142 connected to the main circuit 141, wherein the main circuit 141 is connected to the second metal pads 142 by a positive line 141p and a negative line 141n. Moreover, each of the second metal pads 142 are connected with the outer edges of each of the openings 131, respectively. Therefore, each of the second metal pads 142 and the openings 131 are respectively located over each of the first metal pads 12 when the second thermal-conductive and electric-insulating layer 13 covered the first thermal-conductive and electric-insulating layer 11. Moreover, the anti-soldering layer 16 covering the circuit layer 14 has a plurality of soldering windows 161, used for exposing the second metal pads 142 out.

Through above descriptions, the base framework and structure of the double-layer circuit structure 1 with high heat-dissipation efficiency are completely introduced; next, the technology features and the related efficiencies of the double-layer circuit structure 1 will be further introduced in following paragraphs. A plurality of devices 15 to be welded, such as LED devices, can be disposed on the anti-soldering layer 16 and are respectively soldered on the second metal pads 142 via the soldering windows 161, so as to be electrically connected to the circuit layer 14. Particularly, each of the devices 15 to be welded are soldered on two second metal pads 142, and the solder 2 would flow into the openings 131 through the soldering points between the devices to be welded and the second metal pads 142, so as to sequentially flow onto the first metal pads 12; therefore, the flow path of the solder 2 becomes a shortcut for heat dissipation. By double-layer circuit structure 1, when the LED devices 15 soldered on the second metal pads 142 emit light, the heat produced by the LED devices 15 would be directly and effectively conducted to the first metal pads via the shortcut, without using any interlayer materials.

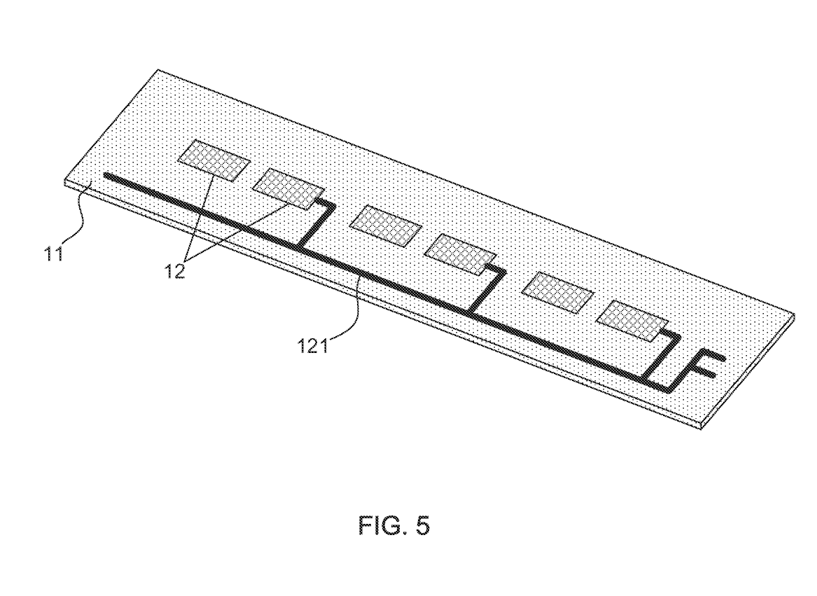

Herein, it needs to further explain that, because of the disposing of the anti-soldering layer 16, the solder 2 would be limited to make vertical flow and get into the openings 131 without making lateral flow, such that the condition of two adjacent second metal pads 142 connecting to each other is sure that will not occur. Moreover, please refer to FIG. 5, there is shown a stereo view of the first thermal-conductive and electric-insulating layer 11. As shown in FIG. 5, for increasing the heat conduction and dissipation, the first thermal-conductive and electric-insulating layer 11 is further formed with at least one connecting line 121 thereon, used for connecting the first metal pads 12; therefore, when the heat produced by the devices 15 to be welded is conducted to the first metal pads 12 via the heat-dissipating shortcut, and then the heat can be further conducted to the connecting line 121 for enhancing heat distribution and heat dissipation.

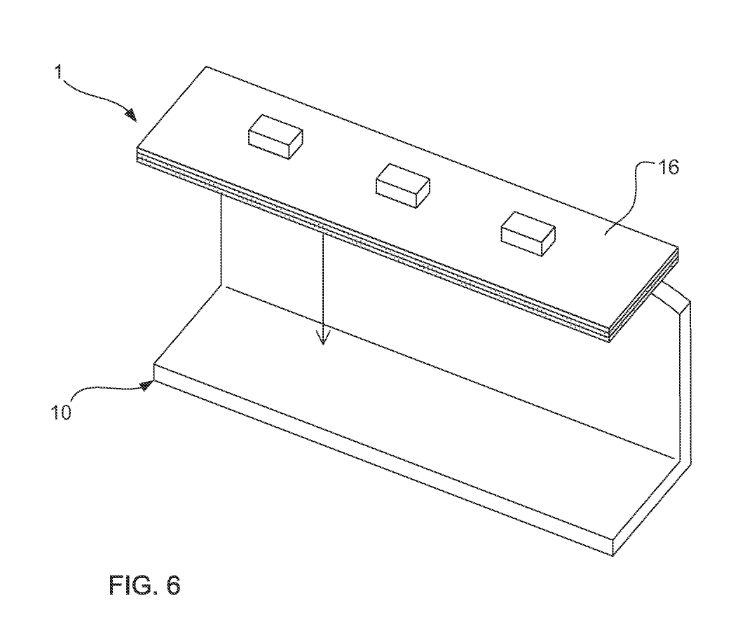

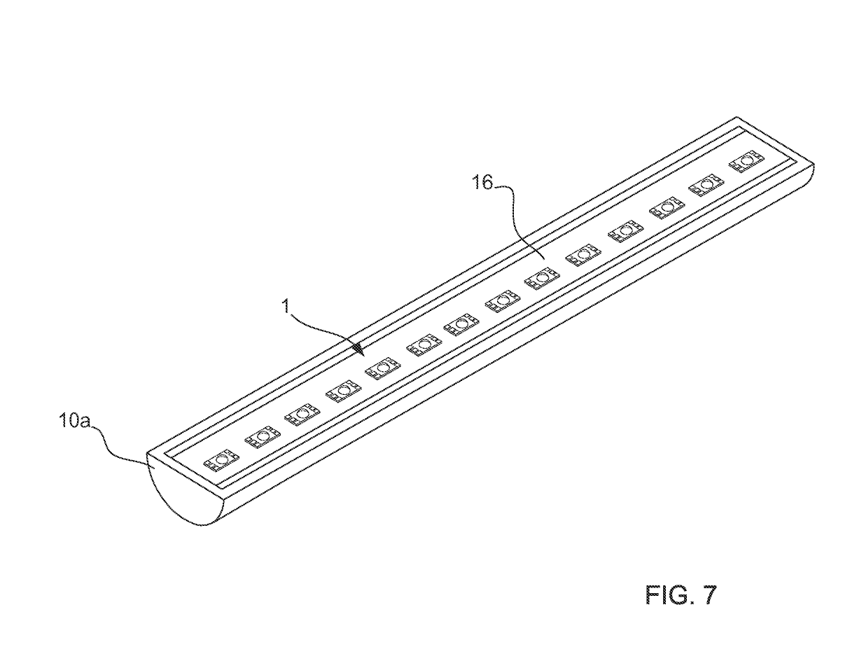

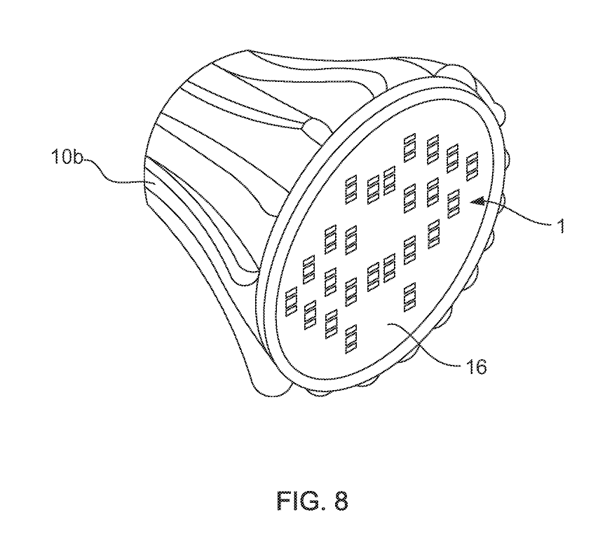

Furthermore, please refer to FIG. 6, FIG. 7 and FIG. 8, there are shown stereo views of an LED backlight module, an LED lamp tube and an LED lamp. As shown in FIG. 6, FIG. 7 and FIG. 8, the double-layer circuit structure 1 of the present invention can be applied in the LED backlight module, the LED lamp tube and the LED lamp. In the LED backlight module of FIG. 6, the shape of the first thermal-conductive and electric-insulating layer 11 and the second thermal-conductive and electric-insulating layer 13 are fabricated to long rectangle for being easily disposed in the bottom of the housing 10. Moreover, in the LED backlight module, the anti-soldering layer 16 can be a white paint sprayed on the circuit layer 14, or be a white reflective sheet disposed on the circuit layer 14.

Besides, the long-rectangular double-layer circuit structure 1 can also be installed into the housing 10a of the LED lamp tube for being an LED device driving circuit. Furthermore, the shape of the first thermal-conductive and electric-insulating layer 11 and the second thermal-conductive and electric-insulating layer 13 are fabricated to circle, so as to make the double-layer circuit structure 1 capable of being disposed in the bottom of the housing 10b of the LED lamp. Similarly, whatever in the LED lamp tube of FIG. 7 or in the LED lamp of FIG. 8, the anti-soldering layer 16 can be a white paint sprayed on the circuit layer 14, or be a white reflective sheet disposed on the circuit layer 14. However, it needs further emphasize that the circular shape and the rectangular shape does not used for limiting the appearance of the double-layer circuit structure 1 of the present invention, that depends on different practical applications of uses or manufactures.

Thus, through the descriptions, the double-layer circuit structure with high heat-dissipation efficiency of the present invention has been completely introduced and disclosed; moreover, the technology features have also been explained. In summary, the present invention has the following advantages:

1. Comparing to the conventional circuit structure with double-layers, the double-layer circuit structure 1 of the present invention does not utilize through holes for being heat-dissipating shortcuts between the top metal pads and the lower metal pads, and replace that by way of forming a plurality of openings on the top thermal-conductive and electric-insulating layer (i.e., the second thermal-conductive and electric-insulating layer 13), so as to facilitate the solder automatically flow into the openings through the soldering points between the devices to be welded and the metal pads, and sequentially flow onto the lower metal layer. Therefore, the flow path of the solder becomes a heat-dissipating shortcut for heat dissipation.

2. Inheriting to above point 1, by such shortcut forming way, it is unnecessary to fill the heat conductive objects into those through holes, and does not need to concern whether the heat conductive objects are fully filled the through holes. Moreover, such shortcut forming way also make the manufacturing process of the circuit structure with double-layers be simplification.

The above description is made on embodiments of the present invention. However, the embodiments are not intended to limit scope of the present invention, and all equivalent implementations or alterations within the spirit of the present invention still fall within the scope of the present invention.

What is claimed is:

1. A double-layer circuit structure with high heat-dissipation efficiency, comprising:
a first thermal-conductive and electric-insulating layer;
a plurality of first metal pads, being disposed on the first thermal-conductive and electric-insulating layer;
a second thermal-conductive and electric-insulating layer, being disposed on the first thermal-conductive and electric-insulating layer, and having a plurality of openings, wherein each of the openings are located over the inner edges of each of the first metal pads, respectively;
a circuit layer, being formed on the second thermal-conductive and electric-insulating layer, and having a main circuit and a plurality of second metal pads connected to the main circuit, wherein each of the second metal pads are connected with the outer edges of each of the openings, respectively; moreover, each of the second metal pads and the openings are respectively located over each of the first metal pads when the second thermal-conductive and electric-insulating layer covered the first thermal-conductive and electric-insulating layer; and
an anti-soldering layer, covering the circuit layer, and having a plurality of soldering windows for exposing the second metal pads out;
wherein a plurality of devices to be welded are respectively soldered on the second metal pads via the soldering windows after being disposed on the anti-soldering layer, such that the devices to be welded are electrically connected to the circuit layer; moreover, each of the devices to be welded being soldered on two second metal pads, and the solder would flow into the openings through the soldering points between the devices to be welded and the second metal pads, so as to sequentially flow onto the first metal pads; therefore, the flow path of the solder becomes a heat-dissipating shortcut for heat dissipation.

2. The double-layer circuit structure with high heat-dissipation efficiency of claim 1, wherein the main circuit consists of a positive line and a negative line.

3. The double-layer circuit structure with high heat-dissipation efficiency of claim 1, wherein the first thermal-conductive and electric-insulating layer is further formed with at least one connecting line thereon, used for connecting the first metal pads.

4. The double-layer circuit structure with high heat-dissipation efficiency of claim 1, wherein the device to be welded is an LED device.

5. The double-layer circuit structure with high heat-dissipation efficiency of claim 1, wherein the shape of the first thermal-conductive and electric-insulating layer and the second thermal-conductive and electric-insulating layer is selected from the group consisting of:
rectangle, circle and combination of above two shapes.

6. The double-layer circuit structure with high heat-dissipation efficiency of claim 3, the anti-soldering layer is a white paint sprayed on the circuit layer.

7. The double-layer circuit structure with high heat-dissipation efficiency of claim 3, the anti-soldering layer is a white reflective sheet disposed on the circuit layer.
